(19) United States
(12) Patent Application Publication
(10) Pub. No.: US 2010/0134776 A1
(43) Pub. Date: Jun. 3, 2010

(54) HIGH REPETITION PULSE POWER SOURCE AND EXPOSURE DEVICE WITH HIGH REPETITION POWER SOURCE

(75) Inventors: Takashi Sakugawa, Kumamoto (JP); Hidenori Akiyama, Kumamoto (JP); Sunao Katsuki, Kumamoto (JP)

Correspondence Address: JORDAN AND HAMBURG LLP, 122 EAST 42ND STREET, SUITE 4000, NEW YORK, NY, 10168, US

(73) Assignee: National University Corporation Kumamoto University, Kumamoto-shi (JP)

(21) Appl. No.: 12/594,097

(22) PCT Filed: Mar. 26, 2008
(86) PCT No.: PCT/JP2008/055670

§ 371 Date: Sep. 30, 2009

(30) Foreign Application Priority Data
Mar. 30, 2007 (JP) 2007-095653

(51) Int. Cl. G03B 27/72; H03K 3/64

(52) U.S. Cl. 355/69; 307/108

(57) ABSTRACT

A pulse power source which can perform high repetition of pulse signals by enhancing the throughput of a pulse source is provided. The pulse power source includes: a charger; an initial-stage capacitor section which is provided with a capacitor charged by the charger; and a magnetic pulse compression circuit which performs magnetic pulse compression of a pulse current generated by discharging a charge from the capacitor at the initial-stage capacitor section and, thereafter, outputs the pulse current. An exposure device which includes the pulse power source is also provided. The pulse power source includes, between the initial-stage capacitor section and the magnetic pulse compression circuit, a transistor which controls timing of discharging a charge from the initial-stage capacitor section, an inductor which constitutes a resonance circuit together with the capacitor at the initial stage capacitor section, and a diode which rectifies the pulse current. The pulse power source further includes a means for preventing the generation of an electric current in the reverse direction in the pulse current.

### BACKGROUND OF THE INVENTION

The present invention relates to a high repetition pulse power source and an exposure device with the high repetition pulse power source.

Recently, a technique which is referred to as a pulse power technique has been attracting attentions. In this pulse power technique, a charge stored in a charge storing means such as a capacitor is outputted instantaneously thus generating large electric power. By using such a technique as a drive device of a semiconductor-lithography excimer laser, a large quantity of current of high voltage is generated, quality of water is improved by applying large electric power instantaneously, micro holes are formed in a cell membrane, or plasma is generated for etching a semiconductor or for forming a film.

In such a pulse power technique, a pulse power source is used for generating large electric power instantaneously. The pulse power source includes an initial-stage capacitor for storing a charge, a magnetic pulse compression circuit which compresses a pulse current which is generated by discharging the charge from the initial-stage capacitor, and a charger which charges the initial-stage capacitor with a charge. The pulse power source can input a pulse current whose pulse width is compressed to a predetermined load (see patent document 1, for example).

As one of semiconductor-element manufacturing devices which use such a pulse power source, an exposure device used in a lithography step is known. Particularly, with respect to the exposure device, along with the refinement of manufacture process rules of semiconductor elements formed on a semiconductor substrate, the further shortening of a wavelength of radiation light is requested so that ultraviolet rays are often used currently.

Further, to radiate extreme ultraviolet rays having a shorter optical wavelength, it is necessary to use a special light source such as an EUV (Extreme Ultra-Violet) lamp. Further, a light source is requested to possess a large quantity of light as much as possible. Accordingly, a high repetition pulse compression power source is used as a means for supplying a large pulse current for allowing the EUV lamp to emit light.

Further, in the exposure device, for enhancing the manufacturing efficiency, there has been a demand for the high repetition performance which can increase the number of times of radiation per unit time as much as possible by increasing a throughput.

In view of the above, inventors of the present invention have proposed, as a pulse power source which satisfies such demands, a pulse power source shown in a circuit diagram of FIG. 4.

The pulse power source includes an initial-stage capacitor 120 which has one end thereof connected to a charger 110 and the other end thereof connected to a ground, and first to fourth capacitors 131 to 134 for compression which are sequentially charged by resonance charging along with discharging of a charge stored in the initial-stage capacitor and compress electric energy by gradually shortening a pulse width of a pulse current generated along with each discharge. A pulse current which is generated along with discharging of a charge from the fourth capacitor 134 is inputted to the EUV lamp 141 which constitutes a load so as to allow the EUV lamp 141 to emit an EUV light.

A booster pulse transformer 135 is provided arranged between the first capacitor 131 and the second capacitor 132, and a voltage is amplified by the booster pulse transformer 135.

The initial-stage capacitor 120 and the first to fourth capacitors 131 to 134 have one end thereof connected to a ground respectively, while at the other end of each component not connected to the ground, the initial-stage capacitor 120 and the first capacitor 131 are connected with each other via an inductor 121, a diode 122 and a semiconductor 123, and the first capacitor 131 is charged by resonance charging using an oscillation circuit constituted of the initial-stage capacitor 120 and the inductor 121. In FIG. 4, numeral 124 indicates a protective diode of a semiconductor switch 123. The control-use semiconductor switch 123 is constituted of an insulation gate bipolar transistor.

A booster pulse transformer 135 is provided between the first capacitor 131 and the second capacitor 132, and a first saturable inductor 136 is provided between the first capacitor 131 and the booster pulse transformer 135 and on an end portion side where the first capacitor 131 is not connected to the ground. The second capacitor 132 is charged by resonance charging using an LC resonance circuit which is constituted of the first saturable inductor 136 and the first capacitor 131.

The second capacitor 132 and the third capacitor 133 are connected with each other via a second saturable inductor 137 on an end portion side where the second capacitor 132 and the third capacitor 133 are not connected to the ground, the third capacitor 133 is charged by resonance charging using an LC resonance circuit which is constituted of the second saturable inductor 137 and the second capacitor 132.

The third capacitor 133 and the fourth capacitor 134 are connected with each other via a third saturable inductor 138 on an end portion side where the third capacitor 133 and the fourth capacitor 134 are not connected to the ground, and the fourth capacitor 134 is charged by resonance charging using an LC resonance circuit which is constituted of the third saturable inductor 138 and the third capacitor 133.

The fourth capacitor 134 is connected with a load 140 via a fourth saturable inductor 139, and discharges a charge to a load 140 by an LC resonance circuit which is constituted of the fourth saturable inductor 139 and the fourth capacitor 134. Here, a magnetic pulse compression circuit is constituted of four capacitors for compression consisting of first to fourth capacitors 131 to 134 and the first to fourth saturable inductors 136 to 139. However, the number of the magnetic pulse compression stages of C-L-C may be one or greater.

Patent document 1: JP-A-11-145794

### SUMMARY OF THE INVENTION

However, in the pulse power source shown in the circuit diagram of FIG. 4, in generating a high-frequency pulse current by performing an ON/OFF control of the control-use semiconductor switch 123 at a high speed, a reverse current is transitionally generated in the pulse current as shown in FIG. 5 due to the characteristic of the diode 122.

Accordingly, in using the pulse power source, the pulse power source can be used only under a limited frequency condition during a reverse recovering time of the diode and hence, there exists a drawback that the throughput of the high repetition pulse power source cannot be enhanced.

Further, in an exposure device which uses such a pulse power source, it is impossible to further shorten a time necessary for exposure for one time and hence, it is difficult to shorten a time necessary for exposure processing thus giving rise to a drawback that the enhancement of operational efficiency is difficult.

The present invention is directed to a high repetition pulse power source which includes: a charger; an initial-stage capacitor section having a capacitor which is charged by the charger; and a magnetic pulse compression circuit for compressing and outputting a pulse current generated by discharging a charge of the capacitor, wherein the high repetition pulse power source includes, between the initial-stage capacitor section and the magnetic pulse compression circuit, a semiconductor switch for controlling timing at which the charge of the capacitor of the initial-stage capacitor section is discharged, a saturable reactor or a saturable inductor which is provided between the initial-stage capacitor section and the magnetic pulse compression circuit, and incorporates an inductor which constitutes a resonance circuit together with the capacitor of the initial-stage capacitor section therein, and a diode for preventing a reverse current, and the high repetition pulse power source further includes, for preventing the generation of a transitional current which flows in the backward direction in a pulse current, a coil formed of secondary winding wound around a core around which first winding which constitutes the inductor is wound, and a reset current generating circuit for supplying a predetermined current which magnetizes the core in the forward direction to the coil. Due to such a constitution, it is possible to prevent the generation of the reverse current in the pulse current by the reverse current prevention means so that the throughput of the high repetition pulse power source can be enhanced thus enabling the higher repetition performance. Further, the resonance circuit for discharging a charge of the initial-stage capacitor section can be made compact.

Further, the pulse power source according to the present invention possesses the following technical features.

(1) The reverse current prevention means is a saturable reactor or a saturable inductor which incorporates the inductor therein and is provided between the initial-stage capacitor section and the magnetic pulse compression circuit, and a reset current generating circuit which resets the saturable reactor or the saturable inductor is provided in the forward direction.

(2) An electrostatic capacitance of the initial-stage capacitor section is approximately ten times or more larger than an electrostatic capacitance of capacitors provided in the magnetic pulse compression circuit.

(3) Capacitors are provided in the magnetic pulse compression circuit in a plurality of stages, and electrostatic capacitances of the capacitors are sequentially increased in order from the capacitor on an input side to the capacitor on an output side.

The present invention is also directed to an exposure device which includes the high repetition pulse power source, the exposure device including: a light source which radiates light for exposure with the supply of an electric current outputted from the high repetition pulse power source; a light quantity measuring means which measures a quantity of light radiated from the light source; and an adjusting means which adjusts the number of times of light emission of the light source based on a result of measurement obtained by the light quantity measuring means. The exposure device of the present invention is also characterized in that the capacitor in the initial-stage capacitor section is charged during a period where the exposure by the light source is stopped.

The exposure device of the present invention is further characterized in that an exposure quantity is controlled corresponding to the number of pulses outputted from the high repetition pulse power source. Due to such a constitution, the number of times of radiation per unit time can be increased and hence, a radiation quantity of light per unit time can be increased whereby a time necessary for exposure processing can be shortened thus enhancing operation efficiency.

According to the present invention, by providing, between the initial-stage capacitor section and the magnetic pulse compression circuit, not only the diode but also the coil formed of the secondary winding wound around the core around which the first winding which constitutes the inductor is wound, and the reset current generating circuit for supplying the predetermined current which magnetizes the core in the forward direction to the coil for preventing the generation of an electric current which flows in the backward direction in a pulse current, it is possible to prevent the generation of the reverse current in the pulse current by the reverse current prevention means and hence, the throughput of the high repetition pulse power source can be enhanced thus further enhancing the high repetition performance of pulse signals.

### BRIEF DESCRIPTION OF THE DRAWINGS

FIG. 1 is an explanatory view of an exposure device according to an embodiment of the present invention;

FIG. 2 is a waveform diagram showing a waveform of a pulse current which flows in a diode portion of the pulse power source according to the embodiment of the present invention;

FIG. 3 is a timing chart showing driving timing of a semiconductor switch;

FIG. 4 is an explanatory view of a conventional pulse power source; and

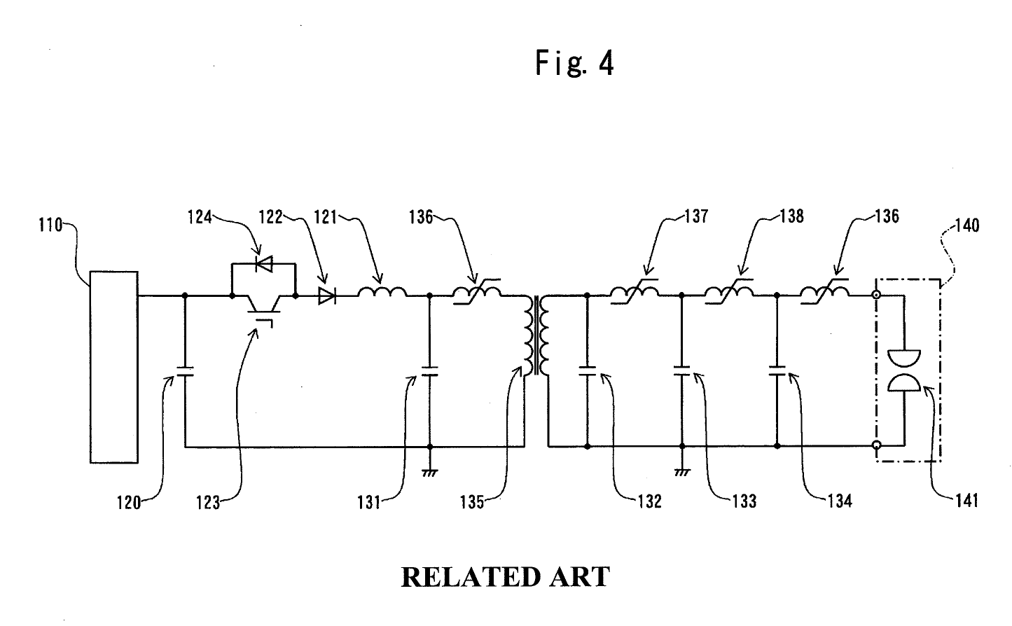

FIG. 5 is a waveform diagram showing a reverse current portion appearing in a pulse current which flows in a diode portion of the conventional pulse power source.

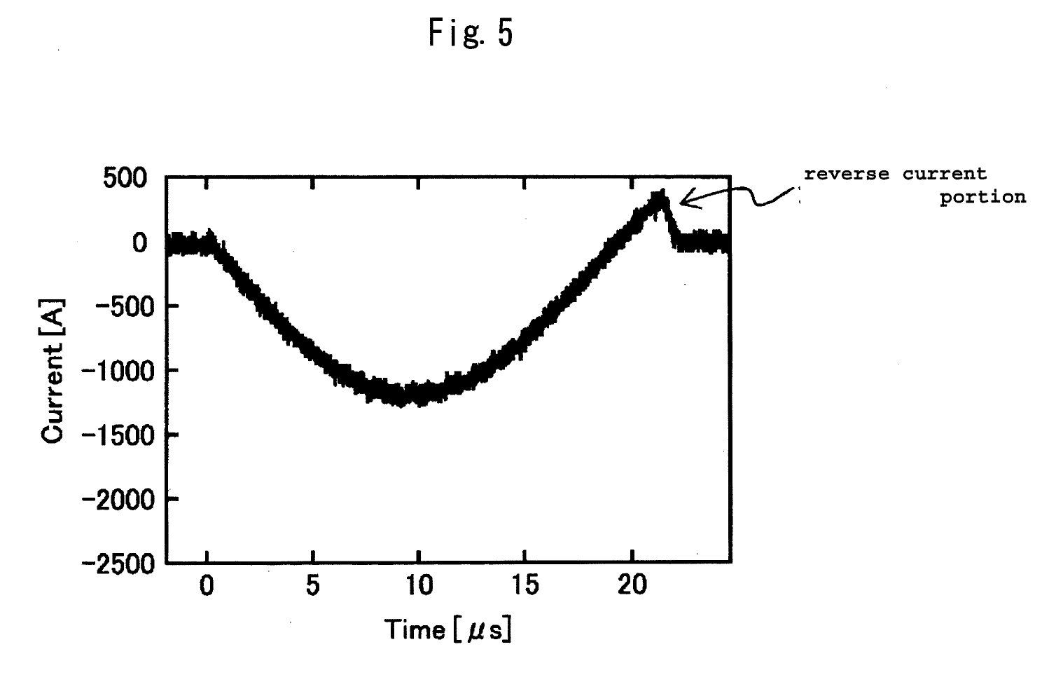

### DETAILED DESCRIPTION OF THE INVENTION

The present invention is directed to a high repetition pulse power source and an exposure device which includes the high repetition pulse power source. In such a high repetition pulse power source which includes a charger, an initial-stage capacitor section which includes a capacitor charged by the charger, and a magnetic pulse compression circuit which performs magnetic pulse compression of a pulse current generated by discharging a charge from the capacitor of the initial-stage capacitor section and outputs a compressed pulse current, the high repetition pulse power source includes a reverse-current preventing means which prevents the generation of an electric current which flows in the reverse direction in the pulse current between the initial-stage capacitor section and the magnetic pulse compression circuit.

That is, a diode is provided between the initial-stage capacitor section and the magnetic pulse compression circuit for preventing a reverse current flow. However, there exists a possibility that an electric current which flows in the reverse-current direction is generated in the pulse current attributed to lowering of a rectifying characteristic of the diode with respect to high frequency. By interrupting the electric current which flows in the reverse direction which cannot be interrupted by the diode using the reverse-current preventing means, frequency of pulse current is increased thus enhancing throughput of the pulse power source.

An embodiment of the present invention is explained in detail hereinafter. In this embodiment, the high repetition pulse power source incorporated into the exposure device is explained. However, the present invention is not limited to a case where the high repetition pulse power source is used as a part of the exposure device but can be also used in the same manner as a conventionally-used pulse power source incorporated in a plasma generating device or an ozone generating device, for example.

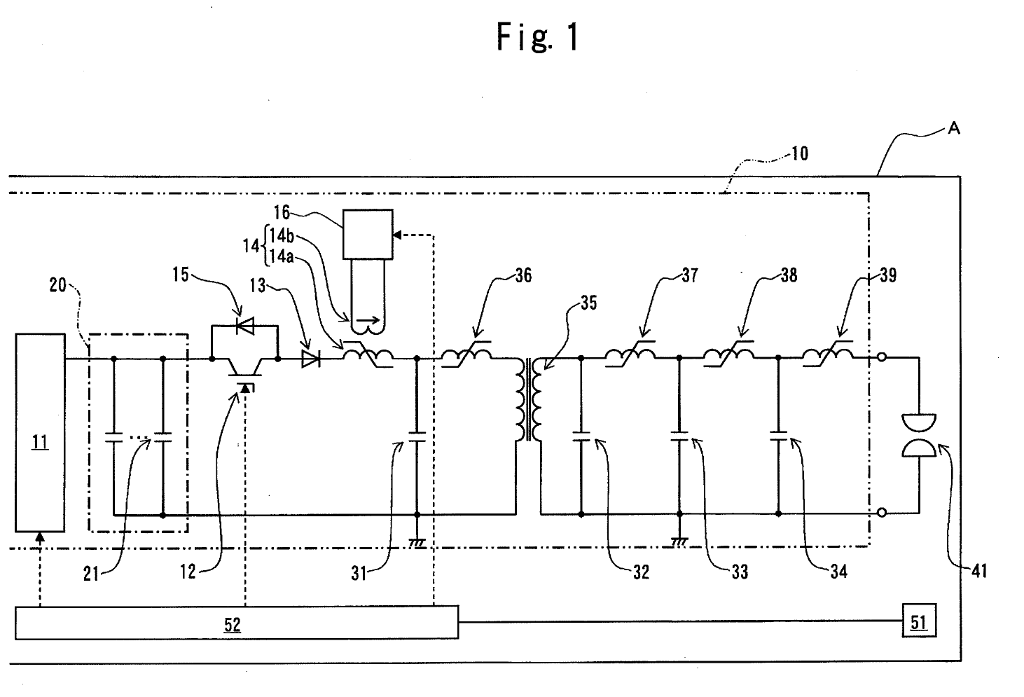

As shown in FIG. 1, the exposure device A includes the high repetition pulse power source 10, an EUV lamp 41 which is connected to the high repetition pulse power source 10, a photo sensor 51 which constitutes a light quantity measuring means for detecting a quantity of light radiated from the EUV lamp 41, and a control part 52 which detects an output signal which is a measurement result outputted from the photo sensor 51 and calculates the quantity of light by analyzing the output signal.

The high repetition pulse power source 10 includes an initial-stage capacitor section 20 constituted of a plurality of capacitors 21 each of which has one end thereof connected to a charger 11 and the other end thereof connected to a ground, and first to fourth capacitors 31 to 34 for compression which compress electric energy by sequentially performing resonance charging along with discharging of a charge stored in the initial-stage capacitor section 20 and by gradually decreasing a cycle of a pulse current generated along with discharging by each capacitor, wherein energy outputted from the fourth capacitor 34 is inputted to the EUV lamp 41 which constitutes a load so that EUV light is radiated from the EUV lamp 41.

A boosting pulse transformer 35 is provided between the first capacitor 31 and the second capacitor 32, and a voltage is amplified by this boosting pulse transformer 35.

The respective capacitors 21 of the initial-stage capacitor section 20 and the first to fourth capacitors 31 to 34 have one end thereof connected to a ground respectively.

The initial-stage capacitor section 20 and the first capacitor 31 are connected to each other via a semiconductor switch 12 formed of a transistor, a diode 13 and an inductor 14a on an end portion side where the initial-stage capacitor section 20 and the first capacitor 31 are not connected to a ground. The first capacitor 31 is charged by resonance charging using an LC resonance circuit which is constituted of the initial-stage capacitor section 20 and the inductor 14a. In FIG. 1, numeral 15 indicates a protective diode for the semiconductor switch 12. The semiconductor switch 12 is formed of an insulation gate bipolar transistor in this embodiment.

The boosting pulse transformer 35 is provided between the first capacitor 31 and the second capacitor 32 and, at the same time, a first saturable inductor 36 is provided between the first capacitor 31 and the boosting pulse transformer 35 on an end portion side of the first capacitor 31 which is not connected to a ground. The second capacitor 32 is charged by resonance charging using the LC resonance circuit constituted of the first saturable inductor 36 and the first capacitor 31.

The second capacitor 32 and the third capacitor 33 are connected to each other via a second saturable inductor 37 on an end portion side where the second capacitor 32 and the third capacitor 33 are not connected to a ground, and the third capacitor 33 is charged by resonance charging using the LC resonance circuit constituted of the second saturable inductor 37 and the second capacitor 32.

The third capacitor 33 and the fourth capacitor 34 are connected to each other via a third saturable inductor 38 on an end portion side where the third capacitor 33 and the fourth capacitor 34 are not connected to a ground, and the fourth capacitor 34 is charged by resonance charging using an LC resonance circuit constituted of the third saturable inductor 38 and the third capacitor 33.

The fourth capacitor 34 is connected to the EUV lamp 41 via a fourth saturable inductor 39, and discharging of a charge to the EUV lamp 41 is performed by an LC resonance circuit constituted of the fourth saturable inductor 39 and the fourth capacitor 34. In this embodiment, a magnetic pulse compression circuit is constituted of four capacitors for compression consisting of the first to the fourth capacitors 31 to 34 and the first to the fourth saturable inductors 36 to 39. However, the number of C-L-C compression stages may be 1 or greater.

In the high repetition pulse power source 10 having such a constitution, the gist of the present invention lies in that a reverse-current preventing means which prevents a reverse current of a pulse current generated by resonance attributed to the capacitor 21 of the initial-stage capacitor section 20 and the inductor 14a is provided between the initial-stage capacitor section 20 and the first capacitor 31 of the magnetic pulse compression circuit.

By preventing the reverse current generated in the pulse current using the reverse-current preventing means, even when frequency of the pulse current is set to frequency higher than an upper limit of frequency restricted based on a characteristic of the diode 13, a reverse current is prevented by the reverse-current preventing means and hence, frequency of the pulse current can be increased.

Accordingly, throughput of the high repetition pulse power source 10 can be enhanced thus further enhancing the high repetition performance of pulse signals.

Here, the reverse-current preventing means is constituted of a saturable reactor 14 or a saturable inductor incorporating the inductor 14a therein which is provided between the initial-stage capacitor section 20 and the first capacitor 31 of the magnetic pulse compression circuit.

Particularly, the saturable reactor 14 or the saturable inductor is provided between the initial-stage capacitor section 20 and the first capacitor 31 of the magnetic pulse compression circuit and, at the same time, a reset current generating circuit 16 which resets the saturable reactor 14 or the saturable inductor is provided in the forward direction.

That is, the reset current generating circuit 16 is configured such that a resetting coil 14b is formed of secondary winding wound around a core around which first winding which constitutes the inductor 14a of the saturable reactor 14 or the saturable inductor is wound, and a predetermined electric current which magnetizes the core in the forward direction is supplied to the resetting coil 14b.

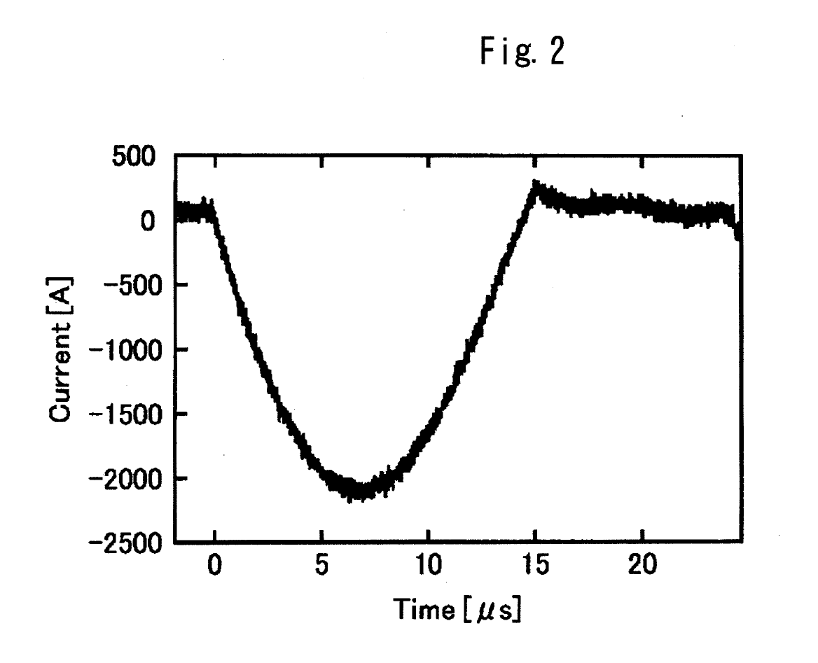

Accordingly, when a reverse current is generated in a pulse current by increasing frequency of the pulse current, by magnetizing the core in the forward direction by supplying a predetermined current to the resetting coil 14b from the reset current generating circuit 16, a reverse current can be surely interrupted as shown in FIG. 2.

Here, the inductor 14a incorporated in the saturable reactor 14 or the saturable inductor constitutes the reverse current preventing means and, at the same time, constitutes a resonance circuit together with the capacitor 21 of the initial-stage capacitor section 20. By charging the first capacitor 31 by resonance charging using such a resonance circuit, the high repetition pulse power source 10 can be formed in a compact shape.

Further, by constituting the initial-stage capacitor section 20 using a plurality of capacitors 21 which are connected to each other in parallel such that the initial-stage capacitor section 20 possesses sufficiently large capacitance compared to the first capacitor 31, a voltage charged to the initial-stage capacitor section 20 can be lowered and hence, the charger 11 can be miniaturized. The high repetition pulse power source 10 can be miniaturized along with this miniaturization of the charger 11. Particularly, it is desirable that the electrostatic capacitance of the initial-stage capacitor section 20 is approximately ten times or more larger than the electrostatic capacitance of the first to fourth capacitors 31 to 34 provided in the magnetic pulse compression circuit.

Here, the electrostatic capacitance of the second to fourth capacitors 32 to 34 are set, for effectively performing the pulse compression, in order of C₃₂≦C₃₃≦C₄, wherein the capacitance of the second capacitor 32 is expressed by C₃₂, the third capacitor 33 is expressed by C₃₃, and the fourth capacitor 34 is expressed by C₃₄. That is, the electrostatic capacitances of the capacitors are sequentially increased in order from the capacitor on an input side to the capacitor on an output side.

In the exposure device A having the high repetition pulse power source 10 which has the above-mentioned constitution, due to the enhancement of the high repetition of pulse signals generated by the high repetition pulse power source 10, light emission intervals for allowing the EUV lamp 41 to emit light can be shortened so that a time necessary for exposure processing can be shortened thus enhancing an operation efficiency.

Particularly, in the exposure device A, usually, a curing reaction of a resist is generated by radiating a predetermined quantity of light to a semiconductor substrate coated with the resist. In this case, instead of the performing the exposure processing by radiating the predetermined quantity of light by performing the continuous emission of light one time from the ECU lamp 41, the exposure processing can be performed by allowing the EUV lamp 41 to intermittently emit light by controlling the number of pulses by the high repetition pulse power source 10 until the cumulative light quantity reaches the predetermined light quantity.

By performing exposure processing by allowing the EUV lamp 41 to intermittently emit light, it is possible to alleviate design conditions of electric characteristics such as a withstand voltage of the high repetition pulse power source 10 and hence, the high repetition pulse power source 10 can be made further compact. Further, the deterioration of the EUV lamp 41 which takes place along with heating of the EUV lamp 41 can be suppressed thus realizing the extension of lifetime of the EUV lamp 41.

Here, in the exposure device A, a quantity of light radiated from the EUV lamp 41 is detected by a photo sensor 51, a result of the detection is inputted to the control part 52 as an output signal, and the control part 52 calculates a quantity of light for each radiation and calculates a cumulative quantity of light based on calculated quantities of respective radiated lights, and exposure processing is finished at a point of time that the cumulative quantity of light reaches a predetermined quantity of light.

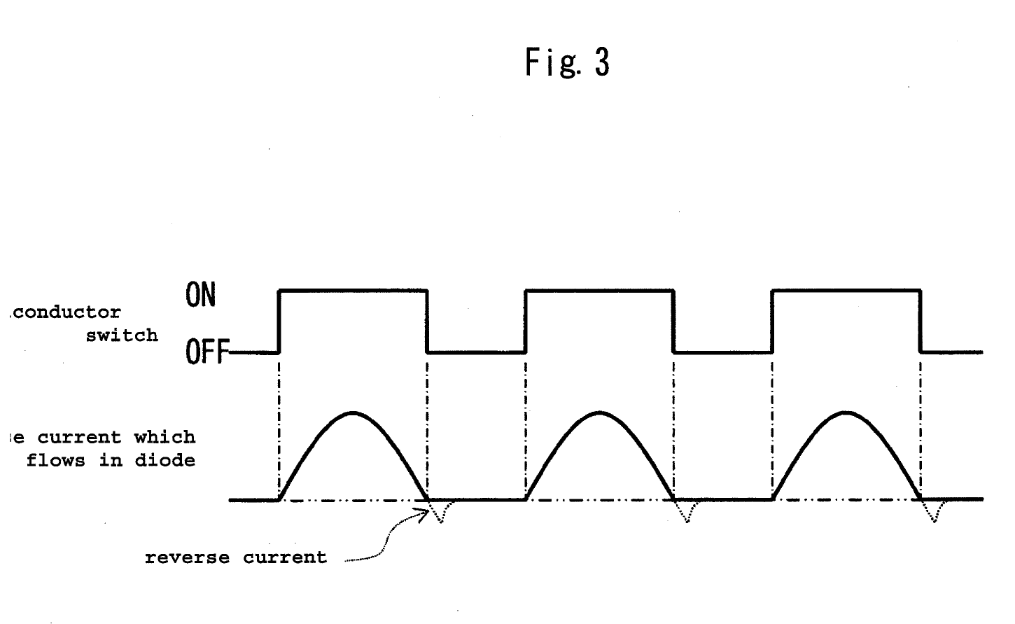

Particularly, until the cumulative quantity of light reaches the predetermined quantity of light, the control part 52 inputs a drive signal which brings the semiconductor switch 12 of the high repetition pulse power source 10 into an ON state at predetermined timing shown in FIG. 3 to the semiconductor switch 12 thus charging the first capacitor 31 by resonance charging and outputting a pulse current.

That is, the control part 52 functions as an adjustment means which adjusts the number of light emission times of the EUV lamp 41 by performing the drive control of the semiconductor switch 12 and hence, the control part 52 can extremely easily perform the light emission control of the EUV lamp 41.

In this manner, by calculating the cumulative quantity of light by the control part 52, even when the EUV lamp 41 is deteriorated with time so that a quantity of light which is radiated by emission of light per one time is lowered, the quantity of light in total can be set to the predetermined quantity of light or more so that the irregularities in manufacture can be suppressed.

According to this embodiment, the control part 52 performs not only the drive control of the semiconductor switch 12 but also a drive control of the reset current generation circuit 16. A core of the saturable reactor 14 or the saturable inductor may be magnetized in the forward direction at predetermined timing by driving the reset current generation circuit 16 based on a control signal from the control part 52.

Further, the control part 52 also performs a drive control of the charger 11. That is, the control part 52 operates the charger 11 so as to charge the initial-stage capacitor section 20 when the exposure by the EUV lamp 41 which constitutes a light source is stopped thus efficiently charging the initial-stage capacitor section 20 and hence, it is possible to allow the high repetition pulse power source 10 to readily start the predetermined outputting whereby operational efficiency can be enhanced.

1. A high repetition pulse power source comprising:
a charger;
an initial-stage capacitor section having a capacitor which is charged by the charger; and
a magnetic pulse compression circuit for compressing and outputting a pulse current generated by discharging a charge of the capacitor, wherein
the high repetition pulse power source includes, between the initial-stage capacitor section and the magnetic pulse compression circuit, a semiconductor switch for controlling timing at which the charge of the capacitor of the initial-stage capacitor section is discharged, a saturable reactor or a saturable inductor which is provided between the initial-stage capacitor section and the magnetic pulse compression circuit, and incorporates an inductor which constitutes a resonance circuit together with the capacitor of the initial-stage capacitor section therein, and a diode for preventing a reverse current; and
the high repetition pulse power source further includes, for preventing the generation of a transitional current which flows in the backward direction in a pulse current, a coil formed of secondary winding wound around a core around which first winding which constitutes the inductor is wound, and a reset current generating circuit for supplying a predetermined current which magnetizes the core in the forward direction to the coil.

2. (canceled)

3. A high repetition pulse power source according to claim 1, wherein an electrostatic capacitance of the initial-stage capacitor section is approximately ten times or more larger than an electrostatic capacitance of capacitors provided in the magnetic pulse compression circuit.

4. A high repetition pulse power source according to claim 1, wherein capacitors are provided in the magnetic pulse compression circuit in a plurality of stages, and electrostatic capacitances of the capacitors are sequentially increased in order from the capacitor on an input side to the capacitor on an output side.

5. An exposure device including the high repetition pulse power source described in claim 1.

6. An exposure device according to claim 5, wherein the exposure device comprises:
a light source which radiates light for exposure with the supply of an electric current outputted from the high repetition pulse power source;
a light quantity measuring means which measures a quantity of light radiated from the light source; and
an adjusting means which adjusts the number of times of light emission of the light source based on a result of measurement obtained by the light quantity measuring means.

7. An exposure device according to claim 6, wherein the capacitor in the initial-stage capacitor section is charged during a period where the exposure by the light source is stopped.

8. An exposure device according to claim 5, wherein an exposure quantity is controlled corresponding to the number of pulses outputted from the high repetition pulse power source.
